(19) United States
(12) Patent Application Publication
(10) Pub. No.: US 2005/0099832 A1
(43) Pub. Date: May 12, 2005

(54) System and method for securing an integrated circuit as against subsequent reprogramming

(75) Inventor: Johannes Becker, Ilmuenster (DE)

Correspondence Address: HITT GAINES, PC;AGERE SYSTEMS INC., PO BOX 832570, RICHARDSON, TX, 75083, US

(73) Assignee: Agere Systems, Incorporated, Allentown, PA (US)

(21) Appl. No.: 10/706,365

(22) Filed: Nov. 12, 2003

(51) Int. Cl. G11C 5/00

(52) U.S. Cl. 365/52

(57) ABSTRACT

For use with an integrated circuit (IC) having a testing port, a system for, and method of, securing the IC as against subsequent reprogramming and an electronic device incorporating the system or the method. In one embodiment, the system includes: (1) port inhibit circuitry located on the IC and modifiable to achieve a configuration that determines an extent to which the testing port is enabled and (2) port access circuitry, coupled to the testing port, that enables the testing port based on the configuration.

### TECHNICAL FIELD OF THE INVENTION

The present invention is directed, in general, to integrated circuits (ICs) and, more specifically, to a system and method for securing an IC as against subsequent reprogramming.

### BACKGROUND OF THE INVENTION

In most countries, mobile phones are subsidized by the operator to tie the end user to the operator's network. To protect his investment, the operator provides a mobile phone that can be used only with his network. To secure this, a SIMLock is used in Global System for Mobile Communications/General Packet Radio Services (GSM/GPRS) phones. The data about the SIMLock state is usually stored in the main flash memory of the phone. By changing the content of that memory, phones can be unlocked and then sold for the use on other networks. This leads to large losses for the operators.

Security against changes of the memory content of a mobile phone is therefore a crucial concern for the mobile operator and subsequently also for vendors of mobile phones. Several software-based algorithms are used in the phones to detect and prevent the change of the memory.

Similar security demands can arise with other electronic devices, such as, for instance, MP3 players, set-top boxes or various other home entertainment devices.

With increasing miniaturization of electronic devices the available space on printed circuit boards decreases, allowing no longer to use space consuming test pads for chip-testing. Therefore nowadays chips typically contain a Joint Test Action Group (JTAG) testing port connected to a boundary scan register, which is used for testing the chip during development and production. Current relevant standards concerning JTAG and boundary scan testing are IEEE/ANSI 1149.1, 1149.4, 1149.5 and 1149.6. JTAG also provides the possibility of in-system programming of a chip and on-board programming of connected chips on a printed circuit board, which do not have to be JTAG compliant themselves. In-system programming of digital devices is dealt with in the related standard IEEE/ANSI 1532.

Once digital devices are distributed to the end user and placed in normal operation, the JTAG port is not used any longer. But the possibility still exists to use the JTAG port for various purposes, e.g., for retrieving of information and component states, for listening to in-device communication and for reprogramming the memory of the electronic device. So, for example, the memory of a mobile phone can be reprogrammed before the integrated software starts to run and by that software-based security algorithms can be circumvented.

This problem of course not only arises for mobile phones, but also for any other electronic device containing a JTAG compliant chip that needs enhanced security against information retrieving and reprogramming.

To solve the problem, a printed circuit board could be designed without JTAG connections, but testing and debugging would be severely hindered. Especially in today's highly miniaturized devices, the capabilities for testing and for in-system and on-board programming provided by JTAG are indispensable.

Therefore, what is needed in the art is a way to accommodate a testing port on an IC without compromising the ICs subsequent security as against unauthorized information retrieving or reprogramming.

### SUMMARY OF THE INVENTION

To address the above-discussed deficiencies of the prior art, the present invention provides, for use with an IC having a testing port, a system for, and method of, securing the IC as against subsequent reprogramming and an electronic device incorporating the system or the method.

In one aspect, the present invention provides a system that includes: (1) port inhibit circuitry located on the IC and modifiable to achieve a configuration that determines an extent to which the testing port is enabled and (2) port access circuitry, coupled to the testing port, that enables the testing port based on the configuration.

In another aspect, the present invention provides a method that includes: (1) modifying port inhibit circuitry located on the IC to achieve a configuration that determines an extent to which the testing port is enabled and (2) enabling the testing port based on the configuration.

In still another aspect, the present invention provides an electronic device that includes: (1) a IC, including: (1a) a testing port, (1b) port inhibit circuitry located on the IC and modifiable to achieve a configuration that determines an extent to which the testing port is enabled and (1c) port access circuitry, coupled to the testing port, that enables the testing port based on the configuration. The electronic device may be, for example, a mobile telephone, a personal digital assistant (PDA), a mobile digital assistant (MDA), an MP3 player or a set-top (video) box for a television.

Accordingly the invention proposes a method for chip design and/or production, wherein a JTAG boundary scan register and a JTAG port according to the standards mentioned above are implemented in the chip, the system and the method calling for the testing (more specifically, JTAG) port to be at least partially disabled. With advantage the step of inhibiting the use of the JTAG port is preferably performed at a point in the production process, when typically no further testing, in-system or on-board-programming via JTAG is necessary. It can also be useful in certain applications not to inhibit completely the use of the JTAG port, but only partially in order to keep a reduced functionality, such as, e.g., the functionality of bypassing the JTAG boundary scan register and by that pipe data in a direct loopback from the TDI (Test Data In) pin to the TDO (Test Data Out) pin of the JTAG port without influencing the chip itself. This can be necessary to keep the JTAG functionality of other chips on the board if the board is provided with a boundary scan path with several JTAG compliant chips serially connected.

The foregoing has outlined, rather broadly, preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

For a more complete understanding of the present invention, reference is now made to the following descriptions taken in conjunction with the accompanying drawings, in which:

FIG. 1 schematically illustrates an IC that is provided with a JTAG boundary scan register and a JTAG port and a system for securing the IC as against subsequent reprogramming constructed according to the principles of the present invention; and

FIG. 2 schematically illustrates a mobile communication device usable in a GSM network and constructed according to the principles of the present invention.

### DETAILED DESCRIPTION

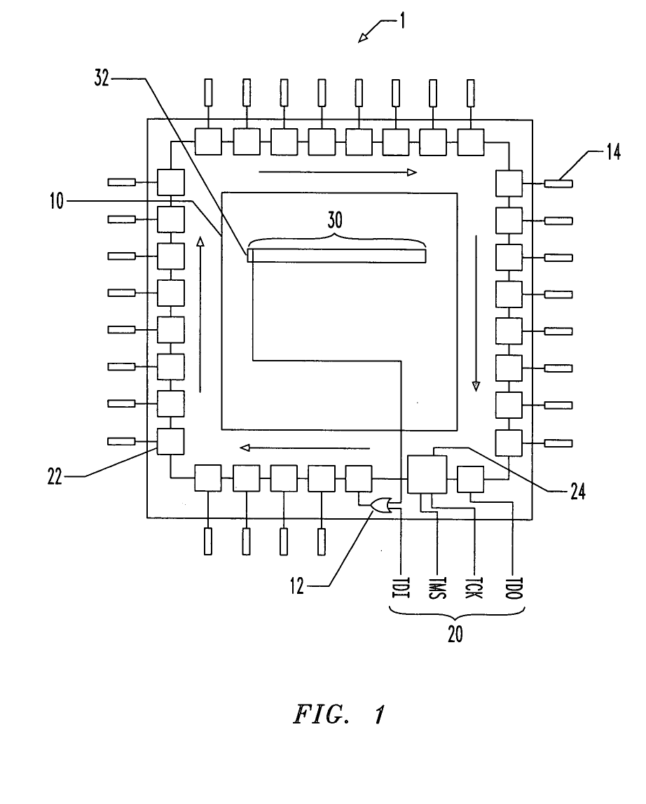

FIG. 1 schematically illustrates an IC 1, which complies to the IEEE 1149.1 and related standards and thus is provided with a JTAG boundary scan register 22 and a JTAG port 20 and a system for securing the IC 1 as against subsequent reprogramming. The JTAG port 20 has four connection pins. The JTAG boundary scan register 22 can be used as a shift register with data shifted in via the JTAG port's TDI (Test Data In) pin and data shifted out via the JTAG port's TDO (Test Data Out) pin. In FIG. 1, the direction of data shift is indicated by arrows. The JTAG port's TCK (Test Clock Input) pin is used to provide a clock separate from the system clock and the JTAG port's TMS (Test Mode Select) pin is used to select test modes defined in the JTAG specification. In this exemplary embodiment, the JTAG test circuitry is controlled by a TAP controller 24 (which constitutes one embodiment of port access circuitry) to which the TMS and TCK pins are connected.

At the device level, the boundary scan elements of the boundary scan register 22 contribute nothing to the functionality of the internal logic 10. The boundary scan path is independent of the function of the device.

During test and development of the IC 1 the JTAG test circuitry can be used for testing and/or for in-system programming of the IC 1 via connections of the internal logic 10 to the JTAG boundary scan register 22. These connections are not shown in FIG. 1. On-board programming of other ICs, like for example flash memory modules, can also be performed via the external connection pins 14 of the IC 1.

The internal logic 10 of the IC 1 is provided with a one-time programmable (OTP) register 30, which constitutes one embodiment of port inhibit circuitry. One bit of this register, the JTAG inhibit bit 32, is reserved for inhibiting the JTAG port. The JTAG inhibit bit is connected with a first input of a NOR gate 12. The other input of the NOR gate 12 is connected with the TDI pin of the JTAG port.

Therefore in this exemplary embodiment the use of the JTAG port is inhibited permanently by storing a “1” in the JTAG inhibit bit (one way of modifying port inhibit circuitry to achieve a configuration that determines an extent to which the JTAG port is enabled), since by this the TDI pin cannot be used subsequently for shifting data in. The programming of the OTP register is irreversible and thus the JTAG port is permanently and completely inhibited.

It is clear to one known in the art that several other possibilities exist to connect the JTAG inhibit bit 32 of the OTP register 30 with the JTAG test circuitry directly or via some kind of logic circuit with the effect of permanently disabling the use of the JTAG port.

The use of the JTAG port can also be partially inhibited by restricting the use to certain functions, such as, e.g., to the functionality of bypassing the JTAG boundary scan register and by that pipe data in a direct loopback from the TDI pin to the TDO pin of the JTAG port (thereby achieving a direct loopback between the TDI pin and the TDO pin). For this purpose a second bit of the OTP register and a suitable logic circuitry can be used.

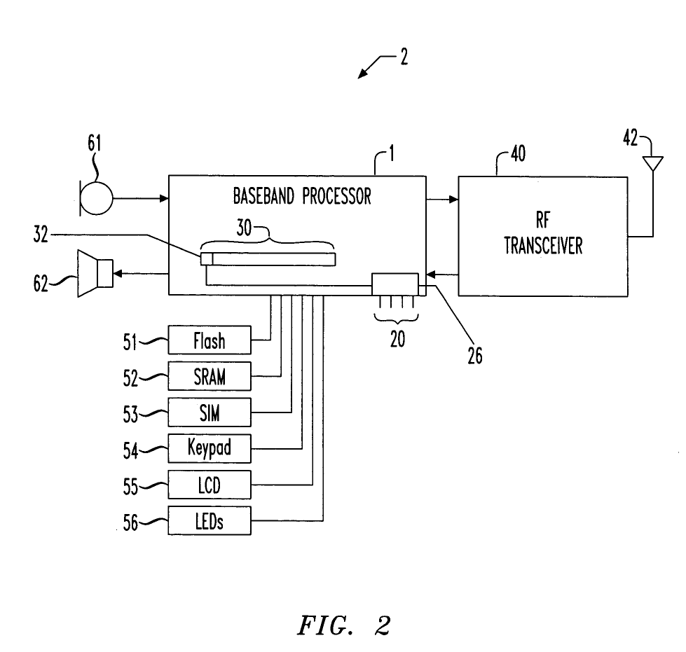

Turning now to FIG. 2, schematically illustrated is a mobile communication device 2 usable in a GSM network. Connected to the baseband processor 1 of the device 2 is a RF transceiver 40 with an antenna 42 accordingly adapted for use in the GSM network. For interaction with the user of the mobile communication device 2, a microphone 61 and a loudspeaker 62 are provided.

In this exemplary embodiment, further components connected to the baseband processor 1 comprise a flash memory module 51, a SRAM memory module 52, a SIM card 53, a keypad 54, a LCD display 55 and LEDs 56.

The baseband processor 1 is provided with a JTAG test circuitry 26 and an according JTAG port 20, which could be used for tampering with the software of the mobile communication device 2 for example to circumvent a SIMLock functionality.

To prevent this the baseband processor 1 is further provided with an OTP register 30, at least one bit 32 of which is suitably linked with the JTAG test circuitry 26.

As already described with regard to FIG. 1, through storing irreversibly an according value in the at least one bit 32 of the OTP register 30, there is no way of activating the JTAG port 20 again, which is therefore inhibited permanently. If the use of the JTAG port is inhibited partially, there is also no way of activating again the permanently disabled functions.

Although the present invention has been described in detail, those skilled in the art should understand that they can make various changes, substitutions and alterations herein without departing from the spirit and scope of the invention in its broadest form.

1. For use with an integrated circuit (IC) having a testing port, a system for securing said IC as against subsequent reprogramming, comprising:
port inhibit circuitry located on said IC and modifiable to achieve a configuration that determines an extent to which said testing port is enabled; and
port access circuitry, coupled to said testing port, that enables said testing port based on said configuration.

2. The system as recited in claim 1 wherein said testing port is a Joint Test Action Group (JTAG) port.

3. The system as recited in claim 1 wherein said port inhibit circuitry comprises an inhibit bit in a one-time programmable register.

4. The system as recited in claim 1 wherein said port inhibit circuitry is configured to be permanently modified prior to delivering said IC to a user thereof.

5. The system as recited in claim 1 wherein said extent is selected from the group consisting of:
fully enabled,
only partially disabled, and
completely disabled.

6. The system as recited in claim 1 wherein said testing port comprises a direct loopback between input and output pins thereof.

7. The system as recited in claim 1 wherein said IC is a baseband chip of a mobile communication device.

8. For use with an integrated circuit (IC) having a testing port, a method of securing said IC as against subsequent reprogramming, comprising:
modifying port inhibit circuitry located on said IC to achieve a configuration that determines an extent to which said testing port is enabled; and
enabling said testing port based on said configuration.

9. The method as recited in claim 8 wherein said testing port is a Joint Test Action Group (JTAG) port.

10. The method as recited in claim 8 wherein said port inhibit circuitry comprises an inhibit bit in a one-time programmable register.

11. The method as recited in claim 8 wherein said modifying comprises permanently modifying said port inhibit circuitry prior to delivering said IC to a user thereof.

12. The method as recited in claim 8 wherein said extent is selected from the group consisting of:
fully enabled,
only partially disabled, and
completely disabled.

13. The method as recited in claim 8 wherein said testing port comprises a direct loopback between input and output pins thereof.

14. The method as recited in claim 8 wherein said IC is a baseband chip of a mobile communication device.

15. An electronic device, comprising:
an integrated circuit (IC), including:
a testing port, port inhibit circuitry located on said IC and modifiable to achieve a configuration that determines an extent to which said testing port is enabled, and
port access circuitry, coupled to said testing port, that enables said testing port based on said configuration.

16. The electronic device as recited in claim 15 wherein said testing port is a Joint Test Action Group (JTAG) port.

17. The electronic device as recited in claim 15 wherein said port inhibit circuitry comprises an inhibit bit in a one-time programmable register.

18. The electronic device as recited in claim 15 wherein said port inhibit circuitry is configured to be permanently modified prior to delivering said IC to a user thereof.

19. The electronic device as recited in claim 15 wherein said extent is selected from the group consisting of:
fully enabled,
only partially disabled, and
completely disabled.

20. The electronic device as recited in claim 15 wherein said electronic device is selected from the group consisting of:
a mobile telephone,
a PDA,
an MDA,
an MP3 player, and
a set-top box.
